(19) United States
(12) Patent Application Publication
(10) Pub. No.: US 2013/0127001 A1
(43) Pub. Date: May 23, 2013

(54) SEMICONDUCTOR PACKAGE AND METHOD OF FABRICATING THE SAME

(71) Applicant: Xintec Inc., Jhongli City (TW)

(72) Inventors: Ying-Nan Wen, Jhongli City (TW); Chien-Hung Liu, Jhongli City (TW); Wei-Chung Yang, Jhongli City (TW)

(73) Assignee: Xintec Inc., Jhongli City (TW)

(21) Appl. No.: 13/674,264

(22) Filed: Nov. 12, 2012

Related U.S. Application Data
(60) Provisional application No. 61/558,713, filed on Nov. 11, 2011.

(51) Int. Cl. H01L 31/0232; H01L 31/18

(52) U.S. Cl. CPC H01L 31/0232; H01L 31/18
USPC 257/432; 438/65

(57) ABSTRACT

A semiconductor package is provided, including a silicon-containing substrate, a photo-sensor chip disposed on the silicon-containing substrate, a plurality of conductive lines electrically connected to the silicon-containing substrate and the photo-sensor chip, an encapsulating layer encapsulating the photo-sensor chip and the conductive lines, and a colloid lens disposed on the encapsulating layer. With the photo-sensor chip stacked on the silicon-containing substrate, a circuit board may have a reduced region that is occupied by the semiconductor package. A method of fabricating the semiconductor package is also provided.

### BACKGROUND OF THE INVENTION

1. Field of the Invention

This invention relates to semiconductor stacking techniques, and, more particularly, to a semiconductor package and a method of fabricating the same.

2. Description of Related Art

With the rapid development of electronic industries, electronic products are designed to have various functionalities and improved performance. In order to meet the requirements of high integration and miniaturization for semiconductor packages, more semiconductor chips and electronic elements are required to be installed on a single packaging substrate. There are a variety of semiconductor packages in the market, including opto-electronic devices and micro-electro-mechanical system (MEMS).

As shown in FIG. 1, a semiconductor package having a photo-sensor chip 11 is provided. The photo-sensor chip 11 and an electronic element 10 are installed on a packaging substrate 1 made of bismaleimide-triazine (BT). The photo-sensor chip 11 is electrically connected to the packaging substrate 1 and the electronic element 10 by conductive lines 12. The conductive lines 12 also electrically connect the electronic element 10 to the packaging substrate 1. The electronic element 10 may be an application specific integrated circuit (ASIC). In subsequent processes, an encapsulating layer (not shown) encapsulates the photo-sensor chip 11 and the electronic element 10, and an lens (not shown) is formed above the photo-sensor chip 11. Solder balls (not shown) are implanted on the packaging substrate 1 such that the semiconductor package can be combined with a circuit board (not shown).

However, since the photo-sensor chip 11 and the electronic element 10 are disposed on the same surface of the packaging substrate 1, the packaging substrate 1 has to have two active regions C and D reserved for the installation of the photo-sensor chip 11 and the electronic element 10 and the engagement of the conductive lines 12. Therefore, the packaging substrate 1 has a usage area W that cannot be reduced, and the semiconductor package occupies an area of the circuit board that cannot be reduced, either. Accordingly, such an electronic product does not meet the requirement of miniaturization.

Therefore, how to solve the problems of the prior art is becoming a popular issue in the art.

### SUMMARY OF THE INVENTION

In view of the above-mentioned problems of the prior art, the present invention provides a semiconductor package and a method of fabricating the same, in which a photo-sensor chip is stacked on an electronic element such as a silicon-containing substrate, a plurality of conductive lines are electrically connected to the silicon-containing substrate and the photo-sensor chip, an encapsulating layer is formed on the silicon-containing substrate and encapsulates the photo-sensor chip and the conductive lines, and a colloid lens is disposed on the encapsulating layer.

Given the above, in the semiconductor package and a method of fabricating the same the photo-sensor chip is stacked on the silicon-containing substrate. As a result, the semiconductor package has a bottom area identical to a bottom area of the silicon-containing substrate, without considering a bottom area of the photo-sensor chip. Therefore, the circuit board has a greatly reduced area that is occupied by the semiconductor package, and the requirement of miniaturization for electronic products is achieved.

### BRIEF DESCRIPTION OF DRAWINGS

The invention can be more fully understood by reading the following detailed description of the preferred embodiments, with reference made to the accompanying drawings, wherein:

FIG. 1 is a cross-sectional view of a semiconductor package according to the prior art;

FIGS. 2A to 2E illustrate a method of fabricating a semiconductor package of a first embodiment according to the present invention; and

FIGS. 3A to 3D illustrate a method of fabricating a semiconductor package of a second embodiment according to the present invention.

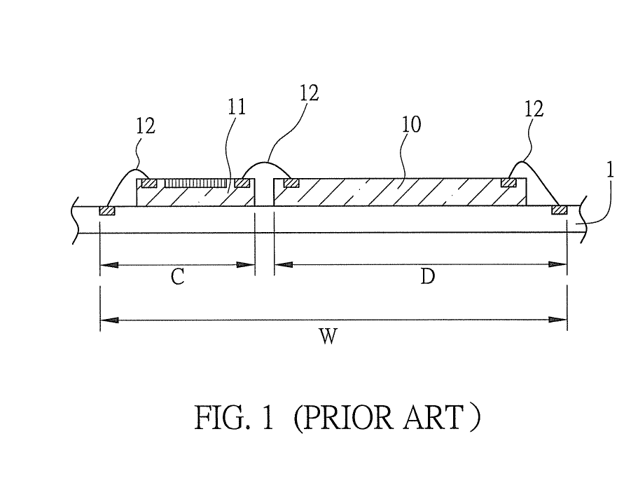

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

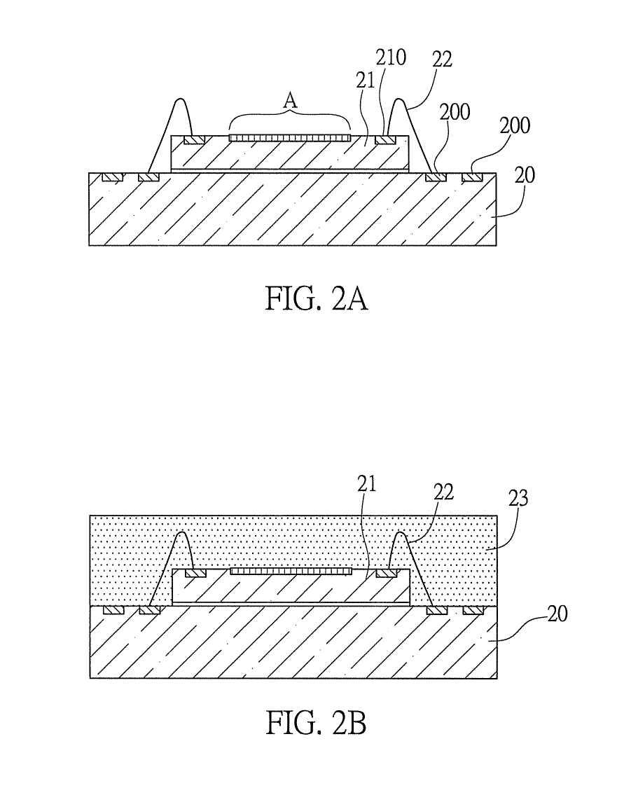

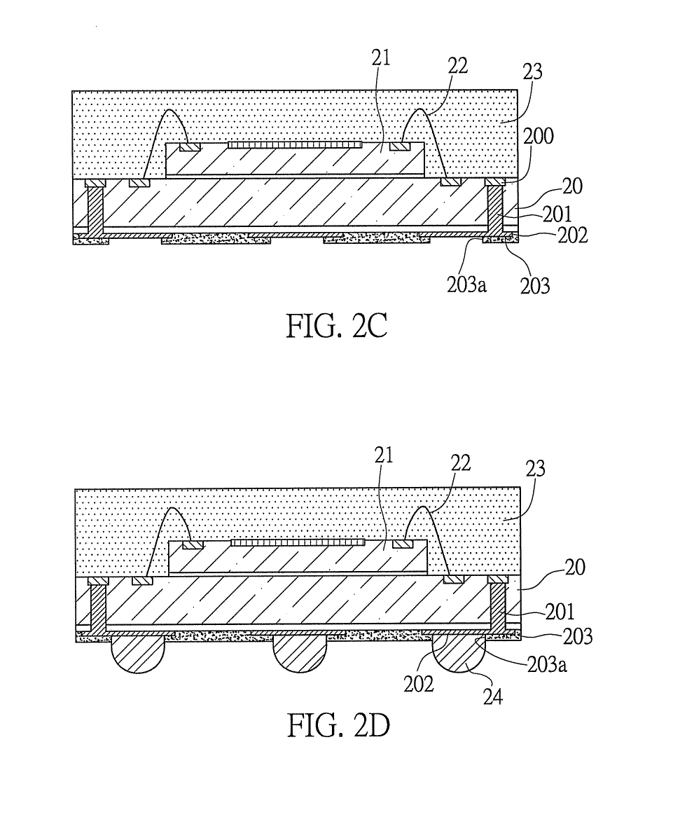

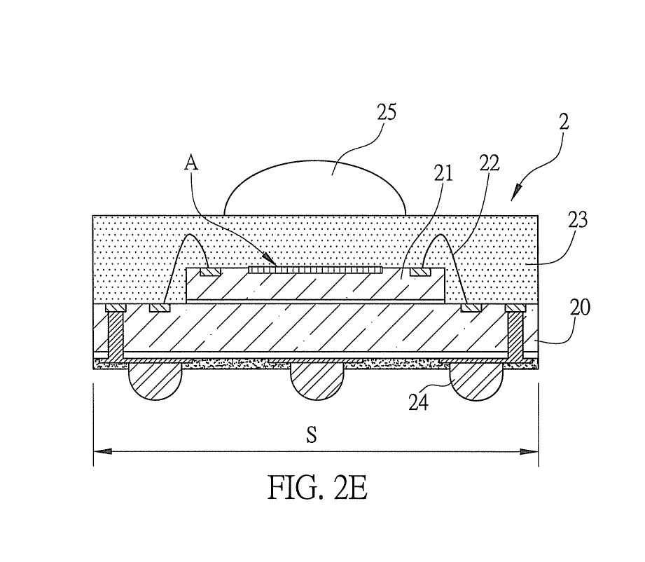

FIGS. 2A to 2E illustrate a method of fabricating a semiconductor package 2 of a first embodiment according to the present invention.

As shown in FIG. 2A, a photo-sensor chip 21 is disposed on a silicon-containing substrate 20. A plurality of conductive pads 200 are disposed on the silicon-containing substrate 20. The photo-sensor chip 21 has a photo-sensor region A. A plurality of electrode pads 210 are disposed on a surface of the photo-sensor chip 21 around the photo-sensor region A.

A wire-bonding process is then performed to connect a plurality of conductive lines 22 to the conductive pads 200 and the electrode pads 210, allowing the conductive lines 22 to be electrically connected to the silicon-containing substrate 20 and the photo-sensor chip 21.

In an embodiment, the silicon-containing substrate 20 can be made of glass or wafer, and has circuits installed therein, to be used as an application specific integrated circuit (ASIC). No limitation is especially placed on the photo-sensor chip 21.

As shown in FIG. 2B, a molding process is performed, in which an encapsulating layer 23 is formed on the silicon-containing substrate 20 to encapsulate the photo-sensor chip 21 and the conductive lines 22.

As shown in FIG. 2C, a plurality of through silicon vias (TSV) 210 are formed in the silicon-containing substrate 20 and penetrate the silicon-containing substrate 20. The through silicon vias 201 are electrically connected to the conductive pads 200. A redistribution layer (RDL) 201 electrically connected to the through silicon vias 201 is formed on a side (the bottom side shown in FIG. 2C) of the silicon-containing substrate 20 where the encapsulating layer 23 is not formed. A protection layer 203 is formed on the bottom side of the silicon-containing substrate 20 and on the redistribution layer 202. Apertures 203a are formed in the protection layer 203, to allow a portion of a surface of the redistribution layer 202 to be exposed therefrom.

As shown in FIG. 2D, a plurality of conductive elements 24 are disposed on the redistribution layer 201 in the apertures 203a. Accordingly, the semiconductor package 2 can be installed on an electronic device (not shown) such as a circuit board by the combination of the conductor elements 24 with the electronic device. In an embodiment, the conductive elements 24 can be solder balls, or pins.

As shown in FIG. 2E, a mold is used to perform another molding process. A colloid lens 25 corresponding to the photo-sensor region A is disposed on the encapsulating layer 23.

In an embodiment, the colloid lens 25 and the encapsulating layer 23 are made of the same material. The colloid lens 25 and the encapsulating layer 23 are not made in the same molding process, in order to prevent the colloid lens 25 from being damaged while the through silicon via 201, the redistribution layer 202 and protection layer 203 are fabricated.

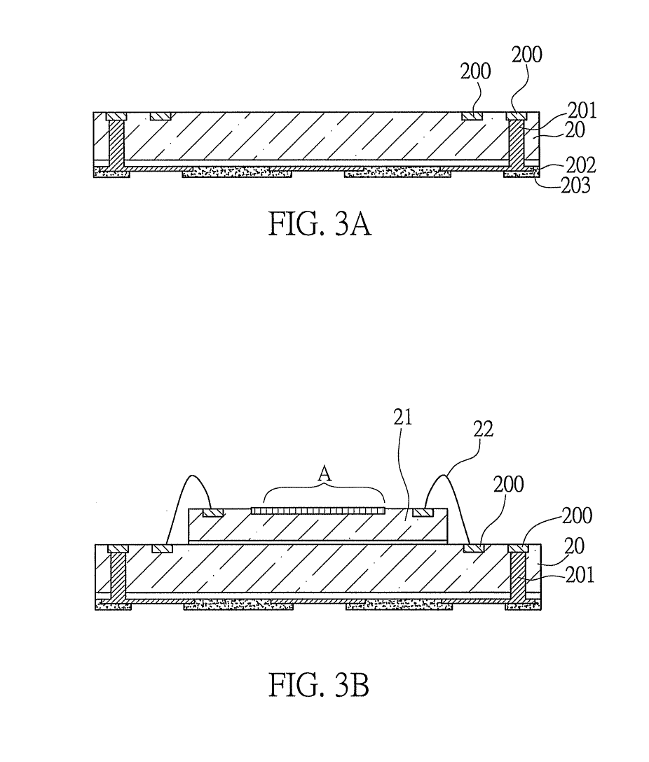

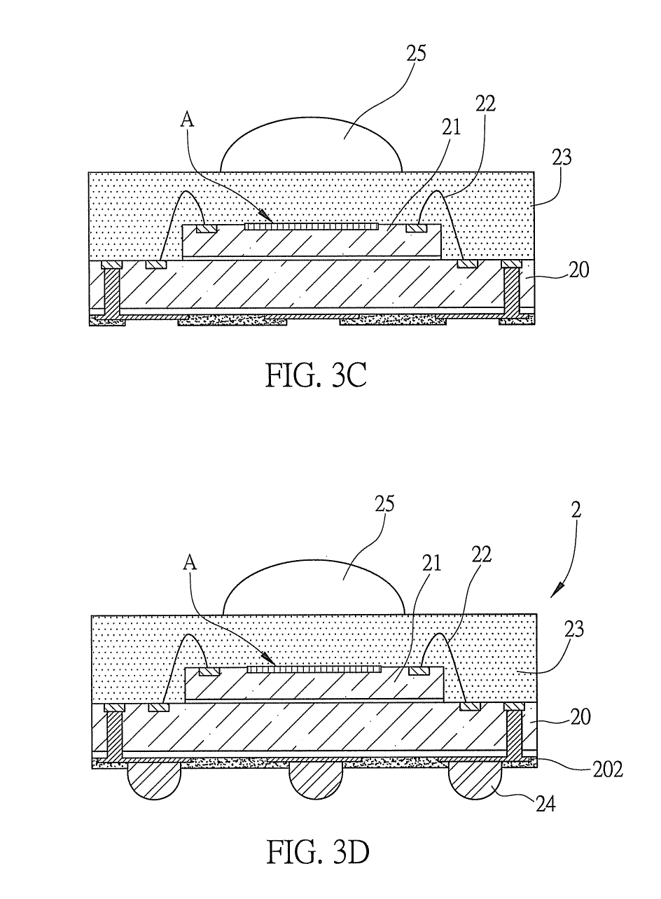

FIGS. 3A to 3D illustrate a method of fabricating the semiconductor package 2 of a second embodiment according to the present invention. The second embodiment differs from the first embodiment in the formation of the through silicon via 201, the redistribution layer 202 and the conductive element 24.

As shown in FIG. 3A, a plurality of through silicon via 201 are formed in a silicon-containing substrate 20 that has conductive pads 200, and a redistribution layer 202 is formed on a bottom side of the silicon-containing substrate 20 and electrically connected to the through silicon via 201. The through silicon via 201 is electrically connected to the conductive pads 200. Then, a protection layer 203 is formed.

As shown in FIG. 3B, a photo-sensor chip 21 having a photo-sensor region A is disposed on the silicon-containing substrate 20. A wire-bonding process is then performed to electrically connect a plurality of conductive lines 22 to the silicon-containing substrate 20 and the photo-sensor chip 21.

As shown in FIG. 3C, an encapsulating layer 23 is formed on the silicon-containing substrate 20 and encapsulates the photo-sensor chip 21 and the conductive lines 22. A colloid lens 25 corresponding to the photo-sensor region A is then disposed on the encapsulating layer 23.

As shown in FIG. 3D, a plurality of conductive element 24 are disposed on the redistribution layer 202.

The present invention further provides a semiconductor package 2, comprising a silicon-containing substrate 20, a photo-sensor chip 21 disposed on the silicon-containing substrate 20, a plurality of conductive lines 22 electrically connected to the silicon-containing substrate 20 and the photo-sensor chip 21, an encapsulating layer 23 formed on the silicon-containing substrate 20, and a colloid lens 25 disposed on the encapsulating layer 23.

The semiconductor package 2 can be applied to a micro-electro-mechanical system (MEMS), and can be fabricated in a wafer scale package (WSP) process.

A plurality of conductive pads 200 are disposed on a top side of the silicon-containing substrate 20, and a redistribution layer 202 is formed on a bottom side of the silicon-containing substrate 20. A plurality of through silicon vias 201 penetrate the silicon-containing substrate 20 and are electrically connected to the conductive pads 200 and the redistribution layer 201.

The photo-sensor chip 21 has a photo-sensor region A. A plurality of electrode pads 210 are disposed on a surface of the photo-sensor chip 21 around the photo-sensor region A.

The conductive lines 22 are connected to the conductive pads 200 and the electrode pads 210, and are electrically connected to the silicon-containing substrate 20 and the photo-sensor chip 21.

The encapsulating layer 23 encapsulates the photo-sensor chip 21 and the conductive lines 22.

The colloid lens 25 corresponds in position to the photo-sensor region A.

The semiconductor package 2 further comprises a plurality of conductive elements 24 disposed on the redistribution layer 202.

Given the above, in the semiconductor package and a method of fabricating the same the photo-sensor chip 21 is stacked on the silicon-containing substrate 20. As a result, the semiconductor package 2 has a bottom area identical to a bottom area S of the silicon-containing substrate 20 (as shown in FIG. 2E), without considering a bottom area of the photo-sensor chip 21. Therefore, the circuit board has a greatly reduced area that is occupied by the semiconductor package 2, and the requirement of miniaturization for electronic products is achieved.

In a method of fabricating a semiconductor package according to the present invention, an ASIC is used as a carrier to carry a photo-sensor chip 21, without using a BT packaging substrate as used in the prior art. Therefore, the material cost is reduced.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A semiconductor package, comprising:
a silicon-containing substrate;
a photo-sensor chip disposed on the silicon-containing substrate;
a plurality of conductive lines electrically connected to the silicon-containing substrate and the photo-sensor chip;
an encapsulating layer formed on the silicon-containing substrate and encapsulating the photo-sensor chip and the conductive lines; and
a colloid lens disposed on the encapsulating layer.

2. The semiconductor package of claim 1, further comprising a plurality of conductive pads disposed on the silicon-containing substrate, and a plurality of electrode pads disposed on the photo-sensor chip, wherein the conductive lines are connected to the conductive pads and the electrode pads and electrically connected to the silicon-containing substrate and the photo-sensor chip.

3. The semiconductor package of claim 1, wherein the photo-sensor chip has a photo-sensor region corresponding in position to the colloid lens.

4. The semiconductor package of claim 1, further comprising a through silicon via penetrating the silicon-containing substrate.

5. The semiconductor package of claim 4, further comprising a redistribution layer formed on a side of the silicon-containing substrate where the photo-sensor chip is not disposed and electrically connected to the through silicon via.

6. The semiconductor package of claim 5, further comprising a conductive element disposed on the redistribution layer.

7. The semiconductor package of claim 1, wherein the colloid lens and the encapsulating layer are made of the same material.

8. A method of fabricating a semiconductor package, comprising:
disposing a photo-sensor chip on a silicon-containing substrate;
electrically connecting a plurality of conductive lines to the silicon-containing substrate and the photo-sensor chip;
forming on the silicon-containing substrate an encapsulating layer that encapsulates the photo-sensor chip and the conductive lines; and
disposing a colloid lens on the encapsulating layer via a mold.

9. The method of claim 8, further comprising disposing a plurality of conductive pads on the silicon-containing substrate, and disposing a plurality of electrode pads on the photo-sensor chip, wherein the conductive lines are connected to the conductive pads and the electrode pads and electrically connected to the silicon-containing substrate and the photo-sensor chip.

10. The method of claim 8, wherein the photo-sensor chip has a photo-sensor region corresponding in position to the photo-sensor region.

11. The method of claim 8, further comprising, prior to forming the colloid lens:
forming a through silicon via penetrating the silicon-containing substrate, and disposing on a side of the silicon-containing substrate where the encapsulating layer is not formed a redistribution layer electrically connected to the through silicon via; and
disposing a conductive element on the redistribution layer.

12. The method of claim 11, further comprising, after forming the colloid lens, disposing a conductive element on the redistribution layer.

13. The method of claim 8, further comprising, prior to disposing the photo-sensor chip, forming a through silicon via penetrating the silicon-containing substrate, and disposing on a side of the silicon-containing substrate wherein the photo-sensor chip is not disposed a redistribution layer electrically connected to the through silicon via.

14. The method of claim 8, wherein the colloid lens and the encapsulating layer are made of the same material.
